(19) United States
(12) Patent Application Publication
(10) Pub. No.: US 2026/0180561 A1
(43) Pub. Date: Jun. 25, 2026

(54) LEVEL SHIFTER CIRCUIT

(71) Applicant: Socionext Inc., Kanagawa (JP)

(72) Inventor: Kyota SHIMIZU, Yokohama-shi (JP)

(21) Appl. No.: 19/541,532

(22) Filed: Feb. 17, 2026

Related U.S. Application Data
(63) Continuation of application No. PCT/JP2023/036085, filed on Oct. 3, 2023.

(51) Int. Cl. H03K 3/356; H03K 19/00; H03K 19/0185

(52) U.S. Cl. CPC H03K 3/356113; H03K 3/356182; H03K 19/0013; H03K 19/0016; H03K 19/0185; H03K 19/018521; H03K 19/018528

(57) ABSTRACT

A level shifter circuit includes first to fourth p-type transistors, first and second n-type transistors, and a pullup circuit. The first n-type transistor and the first p-type transistor are provided between an input node and an output node, and the second p-type transistor is provided between a first power supply and the output node. The second n-type transistor and the third p-type transistor are provided between an inverted input node and an inverted output node, and the fourth p-type transistor is provided between the first power supply and the inverted output node. The pullup circuit is configured to pull up a second node to a third power supply when a first node makes a High to Low transition, and pull up the first node to the third power supply when the second node makes a High to Low transition.

### CROSS-REFERENCE TO RELATED APPLICATIONS

This is a continuation of International Application No. PCT/JP2023/036085 filed on Oct. 3, 2023. The entire disclosure of this application is incorporated by reference herein.

### BACKGROUND

The present disclosure relates to a level shifter circuit that converts the voltage of a signal to a required level when the signal is propagated between circuits to which different power supply voltages are supplied.

A level shifter circuit is provided in an interface part in which a signal is transmitted from a circuit operating at a relatively low voltage inside an LSI to a circuit operating at a relatively high voltage outside the LSI, for example, and used at the conversion of the voltage of the signal.

In recent years, with the miniaturization of transistors, the transistor-tolerable voltage stress (withstanding voltage) is increasingly decreasing. Given this backdrop, a level shifter circuit that performs voltage conversion within a predetermined withstanding voltage range has been conventionally disclosed.

A level shifter circuit disclosed in U.S. Pat. No. 7,151,391 is configured to step up a Low-level voltage, in addition to stepping up a High-level voltage. In this way, by decreasing the voltage between the Low and High levels, the voltage applied across the terminals (e.g., gate-source and source-drain) of a transistor decreases, whereby the voltage stress to the transistor is lightened.

In the configuration in FIG. 1 of the cited patent document, however, the following problem arises: the operation of the level shifter circuit fails to respond to the trend toward lower operating voltages along with requests for lower power consumption and/or the speedup of circuit operation along with requests for higher functionality.

An objective of the present disclosure is solving the above-described problem.

### SUMMARY

According to one mode of the disclosure, a level shifter circuit includes: an input node receiving an input signal that makes a transition between a first power supply and a second power supply lower in potential than the first power supply; a first n-type transistor provided between the input node and a first node and having a gate connected to the first power supply; a first p-type transistor provided between the first node and an output node and having a gate connected to the first power supply; a second p-type transistor provided between the output node and the first power supply and having a gate connected to the first node; an inverted input node receiving an inverted input signal inverted from the input signal; a second n-type transistor provided between the inverted input node and a second node and having a gate connected to the first power supply; a third p-type transistor provided between the second node and a third node and having a gate connected to the first power supply; a fourth p-type transistor provided between the third node and the first power supply and having a gate connected to the second node; and a pullup circuit provided between the first node and the second node, wherein the pullup circuit includes a first pullup circuit for pulling up the second node to a third power supply higher in potential than the first power supply when the first node makes a transition from High level to Low level, and a second pullup circuit for pulling up the first node to the third power supply when the second node makes a transition from High level to Low level.

According to the level shifter circuit of the above mode, since the first pullup circuit operates to pull up the second node to the third power supply when the first node makes a transition from High level to Low level, the voltage drop at the output node is hastened. Therefore, the output signal output to the output node is not delayed. Similarly, since the second pullup circuit operates to pull up the first node to the third power supply when the second node makes a transition from High level to Low level, the voltage rise at the output node is hastened. Therefore, the output signal output to the output node is not delayed. This permits speedup of the circuit in comparison with the case of having no pullup circuit.

Moreover, the level shifter circuit of this mode is constituted by two power supplies, i.e., the first power supply and the third power supply, not using a bias voltage (corresponding to VBIAS in the cited patent document). That is, no circuit for generating a bias voltage is necessary.

According to the present disclosure, in a level shifter circuit, reduction in operating voltage and/or speedup of circuit operation are achieved.

### BRIEF DESCRIPTION OF THE DRAWINGS

FIG. 1 is a circuit diagram showing an example of the configuration of a level shifter circuit according to the first embodiment.

FIG. 2 is a circuit diagram showing an example of the configuration of a pullup circuit.

FIG. 3 is a view showing an example of voltage waveforms at nodes in the level shifter circuit.

FIG. 4 is a circuit diagram showing an example of the configuration of a level shifter circuit according to the second embodiment.

FIG. 5 is a circuit diagram showing an example of the configuration of a level shifter circuit according to the third embodiment.

FIG. 6 is a circuit diagram showing an alteration of the level shifter circuit according to the first embodiment.

FIG. 7 is a circuit diagram showing an alteration of the pullup circuit.

### DETAILED DESCRIPTION

Embodiments of the present disclosure will be described hereinafter. Note that specific numerical values and the like indicated in the following embodiments are mere examples for facilitating the understanding of the disclosure and by no means intended to limit the scope of the disclosure. Note also that nodes and terminals of a circuit and signals passing through such nodes and terminals may be described under the same reference characters, and a power supply and a power supply voltage of the power supply may be described under the same reference character.

### First Embodiment

A level shifter circuit 1, configured with two power supplies, i.e., a first power supply VDD and a third power supply VDDIO, is a circuit that steps up a High-level voltage from VDD to VDDIO and also steps up a Low-level voltage from VSS to VDD. The third power supply VDDIO is higher in voltage than the first power supply VDD. Note that, in the following description, Low level may be simply expressed as ‘L’ and High level as ‘H’.

The level shifter circuit 1 receives an input signal IN that makes transitions between the first power supply VDD and the ground VSS (corresponding to the second power supply) from an input terminal IN (input node in), and outputs an output signal OUT that makes transitions between the third power supply VDDIO and the first power supply VDD from an output terminal OUT (output node out). In other words, the input signal IN is a signal having an amplitude of VDD, and the output signal OUT is a signal having an amplitude of (VDDIO−VDD).

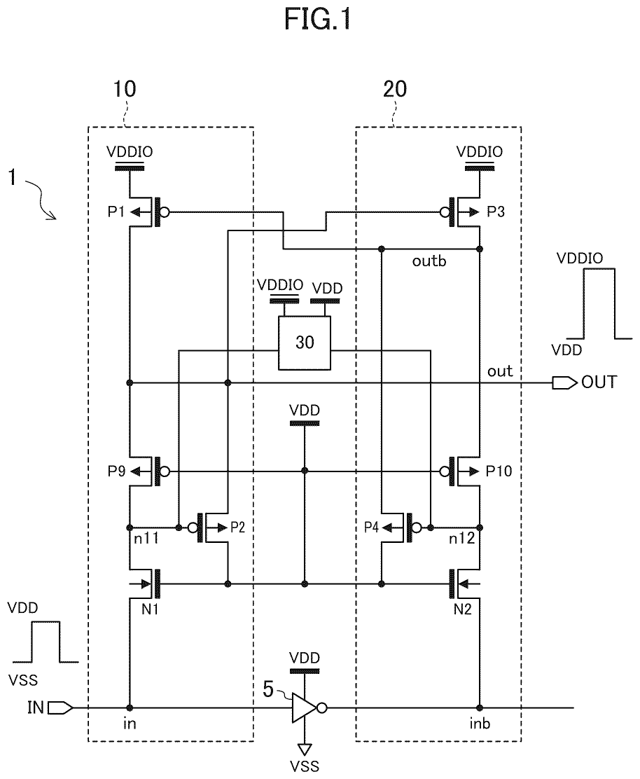

FIG. 1 shows an example of the circuit diagram of the level shifter circuit 1 according to the first embodiment.

The level shifter circuit 1 includes a first circuit 10, a second circuit 20, a pullup circuit 30, and an inverter 5 that inverts the input signal IN to generate an inverted input signal INB.

The inverter 5 receives the input signal IN as an input and outputs the inverted input signal INB to an inverted input node inb of the second circuit 20. The power supply terminal of the inverter 5 is connected to the first power supply VDD, and the ground terminal thereof is connected to the ground VSS. Note that the inverter 5 may be omitted from FIG. 1. For example, a circuit (not shown) preceding the level shifter circuit 1 may generate the input signal IN and the inverted input signal INB, and output these signals to the level shifter circuit 1. This also applies to the other figures (other embodiments).

The first circuit 10 and the second circuit 20 are circuits that step up the input voltage input into the input terminal IN and output the stepped-up voltage from the output terminal OUT. The first circuit 10 and the second circuit 20 have configurations symmetric to each other.

These circuits will be described individually with reference to the drawing.

### —First Circuit—

The first circuit 10 includes an n-type transistor N1 and p-type transistors P1, P2, and P9. Note that n-type transistors and p-type transistors in the present disclosure are MOS transistors, for example.

The input node in of the first circuit 10 is connected to the input terminal IN and receives the input signal IN.

The n-type transistor N1 (corresponding to the first n-type transistor) is provided between the input node in and a node n11 (corresponding to the first node) and has a gate connected to the first power supply VDD. The p-type transistor P9 (corresponding to the first p-type transistor) is provided between the node n11 and the output node out and has a gate connected to the first power supply VDD. In other words, the n-type transistor N1 and the p-type transistor P9 are serially connected between the input node in and the output node out.

Note that, in the present disclosure, the term “connection” is a concept widely covering any electrical connection between components, including, not only the case that components are connected directly, but also the case that components are electrically connected indirectly via a passive element, etc. (not shown).

The p-type transistor P1 (corresponding to the thirteenth p-type transistor) is provided between the third power supply VDDIO and the output node out and has a gate connected to an inverted output node outb (corresponding to the third node).

The p-type transistor P2 (corresponding to the second p-type transistor) is provided between the output node out and the first power supply VDD and has a gate connected to the node n11.

### —Second Circuit—

The second circuit 20 includes an n-type transistor N2 and p-type transistors P3, P4, and P10. The inverted input node inb as the input node of the second circuit 20 is connected to the output of the inverter 5 and receives the inverted input signal INB.

The n-type transistor N2 (corresponding to the second n-type transistor) is provided between the inverted input node inb and a node n12 (corresponding to the second node) and has a gate connected to the first power supply VDD. The p-type transistor P10 (corresponding to the third p-type transistor) is provided between the node n12 and the inverted output node outb and has a gate connected to the first power supply VDD. In other words, the n-type transistor N2 and the p-type transistor P10 are serially connected between the inverted input node inb and the inverted output node outb.

The p-type transistor P3 (corresponding to the fourteenth p-type transistor) is provided between the third power supply VDDIO and the inverted output node outb and has a gate connected to the output node out.

The p-type transistor P4 (corresponding to the fourth p-type transistor) is provided between the inverted output node outb and the first power supply VDD and has a gate connected to the node n12.

As described above, the p-type transistor P1 is connected between the third power supply VDDIO and the output node out, and the p-type transistor P3 is connected between the third power supply VDDIO and the inverted output node outb. Moreover, the gate of the p-type transistor P1 is connected to the inverted output node outb, and the gate of the p-type transistor P3 is connected to the output node out. That is, the p-type transistors P1 and P3 are in the so-called cross-coupled connection. In the following description, the above configuration may be described under the expression of “cross-coupled connection” or “cross-coupled structure.”

### —Pullup Circuit—

The pullup circuit 30 is a circuit provided between the node n11 and the node n12, and operates under supply of the first power supply VDD and the third power supply VDDIO.

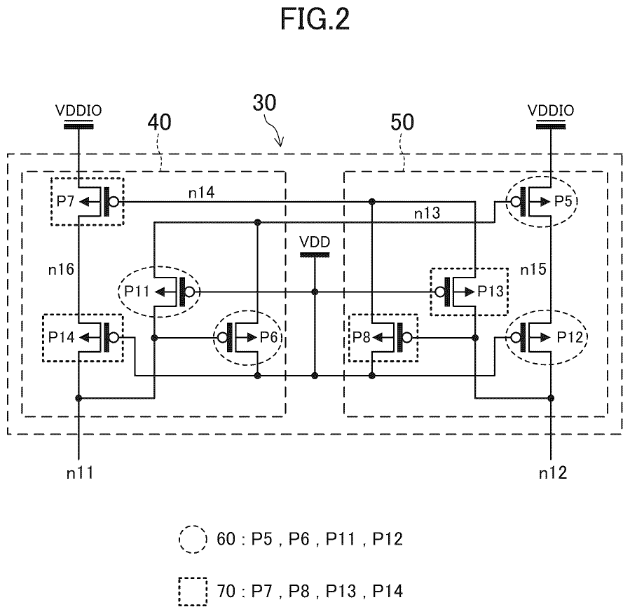

As shown in FIG. 2, the pullup circuit 30 includes a circuit 40 and a circuit 50 that have configurations symmetric to each other.

The circuit 40 includes p-type transistors P6, P7, P11, and P14.

The p-type transistor P7 (corresponding to the eleventh p-type transistor) is provided between the third power supply VDDIO and a node n16 (corresponding to the seventh node) and has a gate connected to a node n14 (corresponding to the sixth node). The p-type transistor P14 (corresponding to the twelfth p-type transistor) is provided between the node n16 and the node n11 and has a gate connected to the first power supply VDD. In other words, the p-type transistor P7 and the p-type transistor P14 are serially connected between the third power supply VDDIO and the node n11.

The p-type transistor P6 (corresponding to the sixth p-type transistor) is provided between a node n13 (corresponding to the fourth node) and the first power supply VDD and has a gate connected to the node n11.

The p-type transistor P11 (corresponding to the fifth p-type transistor) is provided between the node n11 and the node n13 and has a gate connected to the first power supply VDD.

The circuit 50 includes p-type transistors P5, P8, P12, and P13.

The p-type transistor P5 (corresponding to the seventh p-type transistor) is provided between the third power supply VDDIO and a node n15 (corresponding to the fifth node) and has a gate connected to the node n13. The p-type transistor P12 (corresponding to the eighth p-type transistor) is provided between the node n15 and the node n12 and has a gate connected to the first power supply VDD. In other words, the p-type transistor P5 and the p-type transistor P12 are serially connected between the third power supply VDDIO and the node n12.

The p-type transistor P8 (corresponding to the tenth p-type transistor) is provided between the node n14 and the first power supply VDD and has a gate connected to the node n12.

The p-type transistor P13 (corresponding to the ninth p-type transistor) is provided between the node n12 and the node n14 and has a gate connected to the first power supply VDD.

When attention is focused on the functional aspect, the pullup circuit 30 has a function of assisting the step-up conversion operation of the first circuit 10 and the second circuit 20. Specifically, the pullup circuit 30 includes a first pullup circuit 60 and a second pullup circuit 70. The first pullup circuit 60 is a circuit that pulls up the node n12 to the third power supply VDDIO when the node n11 makes a High level to Low level transition. The second pullup circuit 70 is a circuit that pulls up the node n11 to the third power supply VDDIO when the node n12 makes a High level to Low level transition.

In the example of FIG. 2, the first pullup circuit 60 includes the p-type transistors P5, P6, P11, and P12, and the second pullup circuit 70 includes the p-type transistors P7, P8, P13, and P14.

### [Operation of Level Shifter Circuit]

Next, the operation of the level shifter circuit 1 according to this embodiment will be described.

### Operation Example (1-1)

The operation when ‘L’ is input as the input signal IN and ‘L’ is output as the output signal OUT, that is, when the voltage of the input signal is VSS and the voltage of the output signal is VDD will be described. Note that, in the following description, the gate-source voltage Vgs of a transistor will be simply expressed as “Vgs”.

In the first circuit 10, since the input signal IN is ‘L’, the n-type transistor N1 turns ON, whereby the node n11 becomes ‘L’ (voltage VSS), and this turns ON the p-type transistor P2. As a result, the voltage of the output node out becomes VDD, and ‘L’ (voltage VDD) is output to the output terminal OUT. Also, with the voltage of the output node out becoming VDD, the p-type transistor P9 turns OFF.

In the second circuit 20, since the voltage of the output node out is VDD, the p-type transistors P3 and P10 turn ON. With this, the voltages of the node n12 and the inverted output node outb become VDDIO, and this turns OFF the p-type transistors P1 and P4 and the n-type transistor N2.

In the pullup circuit 30, the p-type transistor P6 turns ON, whereby the voltage of the node n13 becomes VDD. This turns OFF the p-type transistor P11 and turns ON the p-type transistor P5 and the p-type transistor P12. As a result, the node n12 is pulled up to the third power supply VDDIO.

On the other hand, since the p-type transistor P13 turns ON and the p-type transistor P8 turns OFF, the voltage of the node n14 becomes VDDIO, whereby the p-type transistor P7 and the p-type transistor P14 turn OFF.

### Operation Example (1-2)

The operation when ‘H’ is input as the input signal IN and ‘H’ is output as the output signal OUT, that is, when the voltage of the input signal is VDD and the voltage of the output signal is VDDIO will be described. Since the first circuit 10 and the second circuit 20 have configurations symmetric to each other and the circuit 40 and the circuit 50 have configurations symmetric to each other, this operation is an operation reciprocal to “Operation Example (1-1)” described above.

In the second circuit 20, since the inverted input signal INB is ‘L’, the n-type transistor N2 turns ON, whereby the node n12 becomes ‘L’ (voltage VSS), and this turns ON the p-type transistor P4. As a result, the voltage of the inverted output node outb becomes VDD, and the p-type transistor P10 turns OFF.

In the first circuit 10, since the voltage of the inverted output node outb is VDD, the p-type transistors P1 and P9 turn ON. With this, the voltages of the node n11 and the output node out become VDDIO, and ‘H’ (VDDIO) is output from the output terminal OUT. Also, the p-type transistor P2, the p-type transistor P3, and the n-type transistor N1 turn OFF.

In the pullup circuit 30, the p-type transistor P8 turns ON, whereby the voltage of the node n14 becomes VDD. This turns OFF the p-type transistor P13 and turns ON the p-type transistor P7 and the p-type transistor P14. As a result, the node n11 is pulled up to the third power supply VDDIO.

On the other hand, since the p-type transistor P11 turns ON and the p-type transistor P6 turns OFF, the voltage of the node n13 becomes VDDIO, whereby the p-type transistor P5 and the p-type transistor P12 turn OFF.

### Operation Example (1-3)

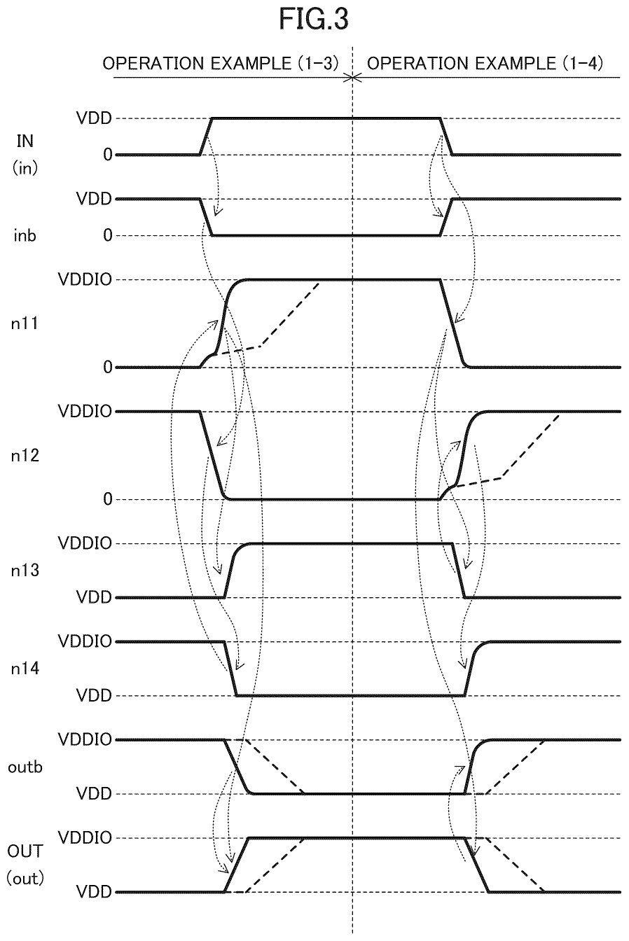

The operation when the input signal IN changes from ‘L’ to ‘H’ and the output signal OUT changes from ‘L’ to ‘H’ will be described with reference to FIG. 3.

The ON/OFF of the transistors and the voltages of the nodes make transitions from the state of “Operation Example (1-1)” to the state of “Operation Example (1-2)” described above. Specific operations will be described hereinafter on a case-by-case basis, for the case where the pullup circuit 30 is provided (Example) and for the case where the pullup circuit 30 is not provided (Comparative Example), separately.

### Operation Example when Pullup Circuit is Provided [Example]

When the input signal IN changes from ‘L’ to ‘H’, the inverted input signal INB changes from ‘H’ to ‘L’. That is, the voltage of the inverted input signal INB falls from VDD. During this process, the Vgs of the n-type transistor N2 exceeds the threshold, allowing the n-type transistor N2 to turn ON, and the voltage of the node n12 falls from VDDIO. At this time, in the pullup circuit 30, the Vgs of the p-type transistor P8 exceeds the threshold, allowing the p-type transistor P8 to start to turn ON. This makes the voltage of the node n14 start to fall from VDDIO.

In the pullup circuit 30, since the node n14 is connected to the gate of the p-type transistor P7 but is not connected to the node n15, no cross-coupled structure is established. Therefore, even though the p-type transistor P8 starts to turn ON, there is no occurrence of “continuity between the third power supply VDDIO and the first power supply VDD” via the p-type transistor P5 and the p-type transistor P8. So, the voltage of the node n14 falls ahead of the voltage of the inverted output node outb.

Therefore, the p-type transistor P7 turns ON ahead of the p-type transistor P1, and the voltage of the node n11 rises ahead of the voltage of the output node out. In other words, the pullup circuit 30 operates to pull up the node n11 to the third power supply VDDIO at the time of the transition of the node n12 from High level to Low level.

Thereafter, the Vgs of the p-type transistor P9 exceeds the threshold, allowing the p-type transistor P9 to turn ON, whereby the node n11 and the output node out are brought into continuity, and then the voltage of the output node out starts to rise. With this, in comparison with the case without the pullup circuit 30 to be described later, the voltage rise at the output node out is hastened, and thus the turning-OFF of the p-type transistor P3 is hastened. Moreover, since the voltage drop at the inverted output node outb and the turning-ON of the p-type transistor P1 are hastened due to the function of the cross-coupled structure, the signal output to the output terminal OUT (signal transition from ‘L’ to ‘H’) is not delayed.

### Operation Example when Pullup Circuit is not Provided [Comparative Example]

When the input signal IN changes from ‘L’ to ‘H’, the inverted input signal INB changes from ‘H’ to ‘L’. That is, the voltage of the inverted input signal INB falls from VDD. During this process, the Vgs of the n-type transistor N2 exceeds the threshold, allowing the n-type transistor N2 to turn ON, and the voltage of the node n12 falls from VDDIO. With this, the Vgs of the p-type transistor P4 exceeds the threshold, allowing the p-type transistor P4 to start to turn ON. This makes the voltage of the inverted output node outb start to fall from VDDIO. Since the p-type transistor P3 is still ON at this time, there occurs a time period when the third power supply VDDIO and the first power supply VDD are in the state of continuity via the p-type transistor P3 and the p-type transistor P4. For this reason, the voltage drop at the inverted output node outb is mild until the p-type transistor P3 starts to turn OFF, causing a delay in the turning-ON of the p-type transistor P1.

Thereafter, when the p-type transistor P1 starts to turn ON, the voltage of the output node out starts to rise from VDD. Since the p-type transistor P2 is still ON at this time, there occurs a time period when the third power supply VDDIO and the first power supply VDD are in the state of continuity via the p-type transistor P1 and the p-type transistor P2. For this reason, the voltage rise at the output node out is mild until the p-type transistor P2 starts to turn OFF, causing a delay in the turning-OFF of the p-type transistor P3. Also, with a delay in the turning-ON of the p-type transistor P9, the voltage rise at the node n11 is mild, causing a delay in the turning-OFF of the p-type transistor P2. Moreover, due to the cross-coupled structure, when the turning-OFF of the p-type transistor P3 is delayed, the turning-ON of the p-type transistor P1 is delayed, and when the turning-ON of the p-type transistor P1 is delayed, the turning-OFF of the p-type transistor P3 is further delayed. As a result, the output signal OUT (transition from ‘L’ to ‘H’) output from the output terminal OUT is delayed.

### Operation Example (1-4)

The operation when the input signal IN changes from ‘H’ to ‘L’ and the output signal OUT changes from ‘H’ to ‘L’ will be described.

The ON/OFF of the transistors and the voltages of the nodes make transitions from the state of “Operation Example (1-2)” to the state of “Operation Example (1-1)” described above. Specific operations will be described hereinafter on a case-by-case basis, for the case where the pullup circuit 30 is provided (example) and for the case where the pullup circuit 30 is not provided (comparative example), separately.

### Operation Example when Pullup Circuit is Provided [Example]

The input signal IN changes from ‘H’ to ‘L’, and the Vgs of the n-type transistor N1 exceeds the threshold, allowing the n-type transistor N1 to turn ON, and the voltage of the node n11 falls from VDDIO. At this time, in the pullup circuit 30, the Vgs of the p-type transistor P6 exceeds the threshold, allowing the p-type transistor P6 to start to turn ON. This makes the voltage of the node n13 fall from VDDIO.

In the pullup circuit 30, since the node n13 is connected to the gate of the p-type transistor P5 but is not connected to the node n16, no cross-coupled structure is established. Therefore, even though the p-type transistor P6 starts to turn ON, there is no occurrence of “continuity between the third power supply VDDIO and the first power supply VDD” via the p-type transistor P7 and the p-type transistor P6. So, the voltage of the node n13 falls ahead of the voltage of the output node out.

Therefore, the p-type transistor P5 turns ON ahead of the p-type transistor P3, and the voltage of the node n12 rises ahead of the voltage of the inverted output node outb. In other words, the pullup circuit 30 operates to pull up the node n12 to the third power supply VDDIO at the time of the transition of the node n11 from High level to Low level.

Thereafter, the Vgs of the p-type transistor P10 exceeds the threshold, allowing the p-type transistor P10 to turn ON, whereby the node n12 and the inverted output node outb are brought into continuity, making the voltage of the inverted output node outb start to rise. With this, in comparison with the case without the pullup circuit 30 to be described later, the voltage rise at the inverted output node outb is hastened, and thus the turning-OFF of the p-type transistor P1 is hastened. Moreover, since the voltage drop at the output node out and the turning-ON of the p-type transistor P3 are hastened due to the function of the cross-coupled structure, the signal output to the output terminal OUT (signal transition from ‘H’ to ‘L’) is not delayed.

### Operation Example when Pullup Circuit is not Provided [Comparative Example]

The input signal IN falls from ‘H’ to ‘L’, and the Vgs of the n-type transistor N1 exceeds the threshold, allowing the n-type transistor N1 to turn ON, and the voltage of the node n11 falls from VDDIO. With this, the Vgs of the p-type transistor P2 exceeds the threshold, allowing the p-type transistor P2 to start to turn ON. This causes the voltage of the output node out to start to fall from VDDIO. Since the p-type transistor P1 is still ON at this time, there occurs a time period when the third power supply VDDIO and the first power supply VDD are in the state of continuity via the p-type transistor P1 and the p-type transistor P2. For this reason, the voltage drop at the output node out is mild until the p-type transistor P1 starts to turn OFF, causing a delay in the turning-ON of the p-type transistor P3.

Thereafter, when the p-type transistor P3 starts to turn ON, the voltage of the inverted output node outb starts to rise from VDD. Since the p-type transistor P4 is still ON at this time, there occurs a time period when the third power supply VDDIO and the first power supply VDD are in the state of continuity via the p-type transistor P3 and the p-type transistor P4. For this reason, the voltage rise at the inverted output node outb is mild until the p-type transistor P4 starts to turn OFF, causing a delay in the turning-OFF of the p-type transistor P1. Also, with a delay in the turning-ON of the p-type transistor P10, the voltage rise at the node n12 is mild, causing a delay in the turning-OFF of the p-type transistor P4. Moreover, due to the cross-coupled structure, when the turning-OFF of the p-type transistor P1 is delayed, the turning-ON of the p-type transistor P3 is delayed, and when the turning-ON of the p-type transistor P3 is delayed, the turning-OFF of the p-type transistor P1 is further delayed. As a result, the output signal OUT (transition from ‘H’ to ‘L’) output from the output terminal OUT is delayed.

### Effects of First Embodiment

As described above, with the configuration of this embodiment, in comparison with the case where the pullup circuit 30 is not provided, the output of a signal to the output terminal OUT is not delayed, and this permits speedup of the circuit.

Specifically, in Operation Example (1-3), since the pullup circuit 30 operates to pull up the node n11 to the third power supply VDDIO when the node n12 makes a transition from High level to Low level, the voltage rise at the output node out is hastened and thus the turning-OFF of the p-type transistor P3 is hastened. Moreover, since the voltage drop at the inverted output node outb and the turning-ON of the p-type transistor P1 are hastened, the output signal OUT (transition from ‘L’ to ‘H’) output from the output terminal OUT is not delayed.

Similarly, in Operation Example (1-4), since the pullup circuit 30 operates to pull up the node n12 to the third power supply VDDIO when the node n11 makes a transition from High level to Low level, the voltage rise at the inverted output node outb is hastened and thus the turning-OFF of the p-type transistor P1 is hastened. Moreover, since the voltage drop at the output node out and the turning-ON of the p-type transistor P3 are hastened, the output signal OUT (transition from ‘H’ to ‘L’) output from the output terminal OUT is not delayed.

Note that, in the level shifter circuit 1 of this embodiment, since the inverter 5 is provided, the propagation time of a signal from the input terminal IN to the output terminal OUT is longer in Operation Example (1-3) than in Operation Example (1-4). Therefore, as the propagation time of a signal further increases with the trend toward lower operating voltages, this difference in propagation time will be further widened. In this embodiment, however, this problem can be prevented.

Also, the level shifter circuit 1 of this embodiment is configured with two power supplies, i.e., the first power supply VDD and the third power supply VDDIO, not using a bias voltage (corresponding to VBIAS in the cited patent document). That is, no circuit for generating a bias voltage is necessary.

### Second Embodiment

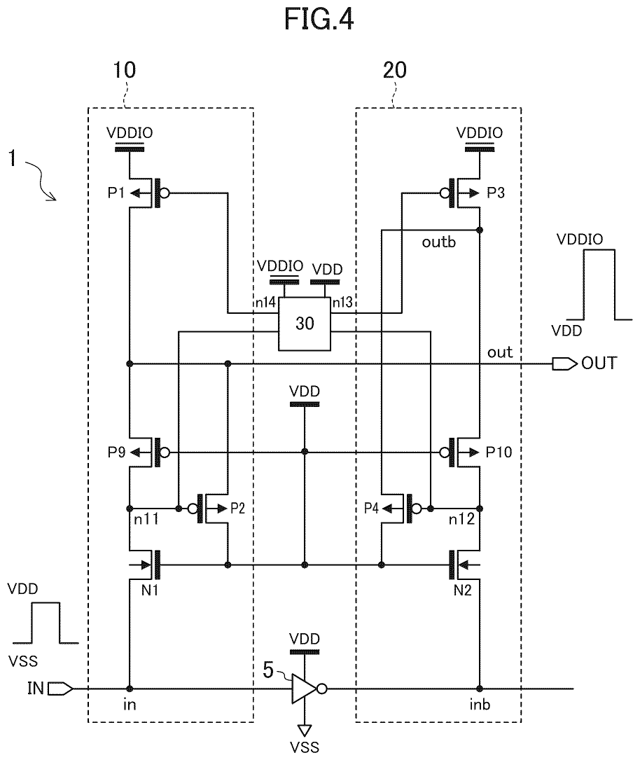

FIG. 4 shows an example of the circuit diagram of a level shifter circuit 1 according to the second embodiment. In FIG. 4, components corresponding to those in FIG. 1 are denoted by the same reference characters. The following description will be made centering on differences from the first embodiment. Note that elements (e.g., transistors and inverters) denoted by the same reference characters in FIGS. 1 and 4 are not intended to be the same in various design parameters, process parameters, and the like. That is, configurations in which elements denoted by the same reference characters in FIGS. 1 and 4 have parameters different from each other also fall within the technical scope of the present disclosure. This also applies to the relationships between other drawings.

The level shifter circuit 1 of this embodiment is configured to further speed up the rise of the voltages of the output node out and the inverted output node outb, in comparison with the first embodiment.

In this embodiment, in the first circuit 10, the gate of the p-type transistor P1 is connected to the node n14 (see FIG. 2) in the pullup circuit 30, in place of the inverted output node outb in the first embodiment. Also, in the second circuit 20, the gate of the p-type transistor P3 is connected to the node n13 (see FIG. 2) in the pullup circuit 30, in place of the output node out in the first embodiment.

### [Operation of Level Shifter Circuit]

Next, the operation of the level shifter circuit 1 according to this embodiment will be described. Description here will be made centering on differences from the description of the operation of the level shifter circuit 1 according to the first embodiment.

### Operation Example (2-1)

The operation when the input signal IN changes from ‘L’ to ‘H’ will be described.

In the first embodiment, the p-type transistor P7 turns ON ahead of the p-type transistor P1, the voltage of the node n11 rises ahead of the voltage of the output node out, and thereafter, with the p-type transistor P9 turning ON, the voltage of the output node out rises.

By contrast, in this embodiment, since the gates of the p-type transistor P7 and the p-type transistor P1 are connected to the common node n14, these transistors turn ON at the same timing. Therefore, the voltage of the node n11 and the voltage of the output node out rise at the same timing. Also, since the p-type transistor P1 and the p-type transistor P3 are not in the cross-coupled structure, the voltage of the output node out rises irrespective of the operation of the p-type transistor P3. Therefore, in comparison with the first embodiment, the voltage of the output node out can be raised hastily.

### Operation Example (2-2)

The operation when the input signal IN changes from ‘H’ to ‘L’ will be described.

As in the case of Operation Example (1-4) described above, in this operation example, the first circuit 10 and the second circuit 20 perform reciprocal operations in comparison with Operation Example (2-1). So, the voltage of the inverted output node outb rises irrespective of the operation of the p-type transistor P1. Therefore, in comparison with the first embodiment, the voltage of the inverted output node outb can be raised hastily.

### Effects of Second Embodiment

As described above, according to this embodiment, in comparison with the first embodiment, the voltage of the output node out and the voltage of the inverted output node outb can be raised hastily. This permits speedup of the circuit in comparison with the first embodiment.

### Third Embodiment

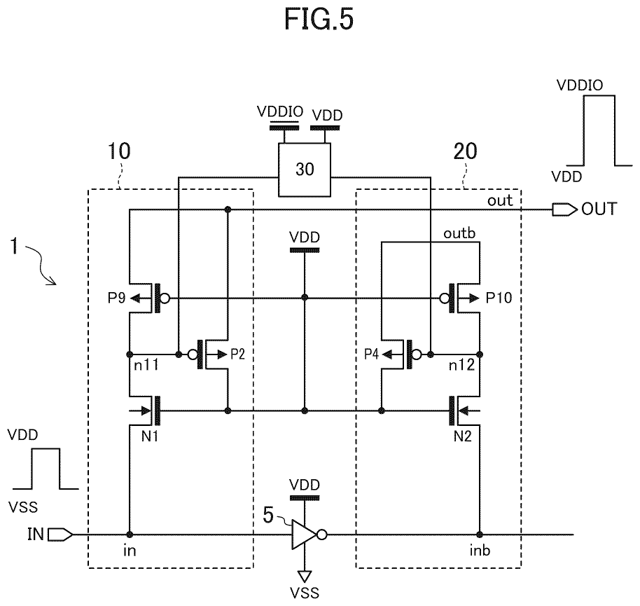

FIG. 5 shows an example of the circuit diagram of a level shifter circuit 1 according to the third embodiment. In FIG. 5, components corresponding to those in FIG. 1 are denoted by the same reference characters. The following description will be made centering on differences from the other embodiments.

In the level shifter circuit 1 of this embodiment, the p-type transistor P1 and the p-type transistor P3 are deleted from the configurations of the first embodiment and the second embodiment. And, the drive capability, i.e., transistor size of the p-type transistor P7 may be set so that the p-type transistor P7 can take on the operation of the p-type transistor P1 in the first and second embodiments, for example. Similarly, the drive capability, i.e., transistor size of the p-type transistor P5 may be set so that the p-type transistor P5 can take on the operation of the p-type transistor P3.

### [Operation of Level Shifter Circuit]

In this embodiment, with the turning-ON of the p-type transistor P5 (see FIG. 2) and the p-type transistor P7 (see FIG. 2) of the pullup circuit 30, the voltages of the node n11, the node n12, the output node out, and the inverted output node outb are raised. Therefore, the level shifter circuit 1 of this embodiment also operates similarly to that of the second embodiment, and can obtain equal effects.

### Effects of Third Embodiment

As described above, according to this embodiment, the level shifter circuit 1 operates similarly to that of the second embodiment, and can obtain equal effects.

Moreover, since it is unnecessary to place the p-type transistor P1 and the p-type transistor P3 and wiring for these transistors (including ones in transistor placement regions and wiring regions), the circuit area can be reduced in comparison with the first embodiment and the second embodiment. Further reduction in circuit area will be possible when it is unnecessary to expand the drive capabilities of the p-type transistor P5 and the p-type transistor P7 as in the case of using control signals (e.g., enable/disable signals) lower in speed than clocks and data signals, for example.

Note that the technique in the present disclosure is applicable, not only to the configurations described in the above embodiments, but also to embodiments appropriately subjected to changes, replacements, additions, and omissions from the above embodiments. Also, the components described in the above embodiments can be combined to provide a new embodiment.

### <Alteration>

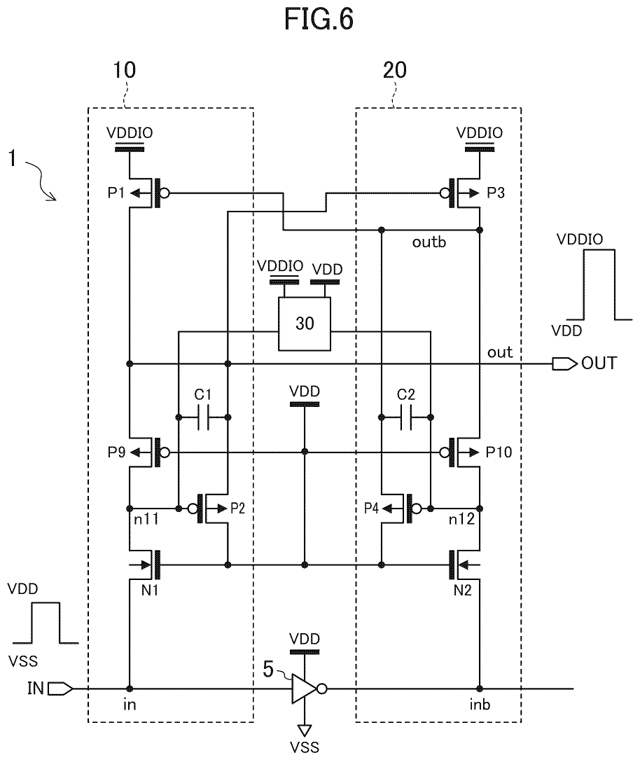

FIG. 6 shows an alteration of the level shifter circuit 1 according to the first embodiment. In FIG. 6, components corresponding to those in FIG. 1 are denoted by the same reference characters. The following description will be made centering on differences from the first embodiment.

The level shifter circuit 1 of this alteration has a capacitor C1 between the output node out and the node n11 and a capacitor C2 between the inverted output node outb and the node n12, in addition to the configuration of the first embodiment.

The configurations of the capacitor C1 and the capacitor C2 are not specifically limited. For example, as the capacitor C1 and the capacitor C2, capacitive elements may be used, or transistor capacitances such as a gate capacitance and a source-drain (S/D) capacitance may be used. This also applies to a capacitor C3 and a capacitor C4 to be described later.

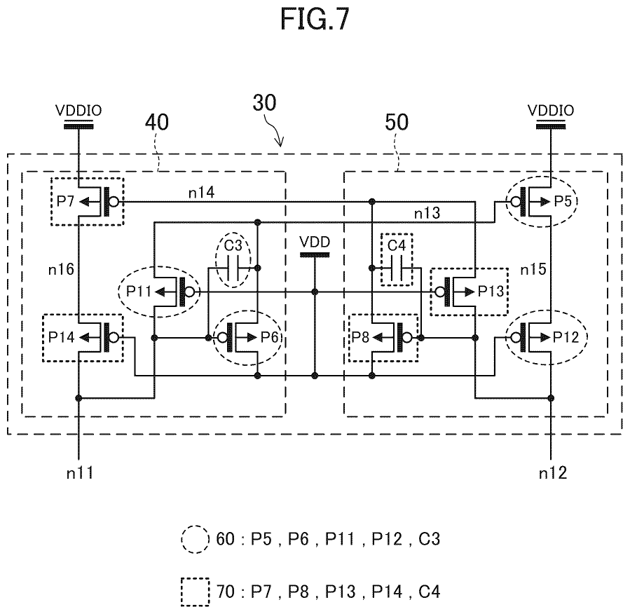

The pullup circuit 30 may have the same configuration as that in the first embodiment (see FIG. 2), or may have a configuration shown in FIG. 7. To state specifically, the first circuit 10 and the second circuit 20 shown in FIG. 1 and the pullup circuit 30 shown in FIG. 7 may be combined together. Alternatively, the first circuit 10 and the second circuit 20 shown in FIG. 6 and the pullup circuit 30 shown in FIG. 2 or the pullup circuit 30 shown in FIG. 7 may be combined together.

### —Pullup Circuit—

FIG. 7 shows another configuration example of the pullup circuit 30. In FIG. 7, components corresponding to those in FIG. 2 are denoted by the same reference characters.

The pullup circuit 30 of FIG. 7 has the capacitor C3 between the node n11 and the node n13 and the capacitor C4 between the node n12 and the node n14, in addition to the configuration of FIG. 2. In the example of FIG. 7, the first pullup circuit 60 includes the capacitor C3 in addition to the p-type transistors P5, P6, P11, and P12 described above. The second pullup circuit 70 includes the capacitor C4 in addition to the p-type transistors P7, P8, P13, and P14 described above.

### [Operation of Level Shifter Circuit]

Next, the operation of the level shifter circuit 1 according to this alteration will be described. In this alteration, the operations of the first circuit 10, the second circuit 20, and the pullup circuit 30 will be described collectively.

### —Operation at Voltage Rise at Output Node/Inverted Output Node—

At the time of voltage rise at the output node out, the pullup circuit 30 raises the voltage of the node n11, and the p-type transistor P9 turns ON, bringing the output node out and the node n11 into continuity, whereby the voltage rise at the output node out is assisted. Thus, the voltage rise at the output node out can be hastened.

Similarly, at the time of voltage rise at the inverted output node outb, the pullup circuit 30 raises the voltage of the node n12, and the p-type transistor P10 turns ON, bringing the inverted output node outb and the node n12 into continuity, whereby the voltage rise at the inverted output node outb is assisted. Thus, the voltage rise at the inverted output node outb can be hastened.

At this time, having the capacitor C1 additionally provided, the voltage of the output node out rises with the voltage rise at the node n11 even before the p-type transistor P9 turns ON. Similarly, having the capacitor C2 additionally provided, the voltage of the inverted output node outb rises with the voltage rise at the node n12 even before the p-type transistor P10 turns ON.

Also, having the capacitor C3 additionally provided, the voltage of the node n13 rises even before the p-type transistor P11 turns ON. Similarly, having the capacitor C4 additionally provided, the voltage of the node n14 rises even before the p-type transistor P13 turns ON.

### —Operation at Voltage Drop at Output Node/Inverted Output Node—

At the time of voltage drop at the output node out, the n-type transistor N1 turns ON, causing the voltage of the node n11 to fall, and after the p-type transistor P9 turns OFF, the p-type transistor P2 turns ON, whereby the voltage of the output node out falls down to the voltage of the first power supply VDD. Similarly, at the time of voltage drop at the inverted output node outb, the n-type transistor N2 turns ON, causing the voltage of the node n12 to fall, and after the p-type transistor P10 turns OFF, the p-type transistor P4 turns ON, whereby the voltage of the inverted output node outb falls down to the voltage of the first power supply VDD.

At this time, having the capacitor C1 additionally provided, the voltage of the output node out falls with the voltage drop at the node n11 even before the p-type transistor P2 turns ON. Similarly, having the capacitor C2 additionally provided, the voltage of the inverted output node outb falls with the voltage drop at the node n12 even before the p-type transistor P4 turns ON.

Also, having the capacitor C3 additionally provided, the voltage of the node n13 falls even before the p-type transistor P6 turns ON. Similarly, having the capacitor C4 additionally provided, the voltage of the node n14 falls even before the p-type transistor P8 turns ON.

### [Effects of Alteration]

As described above, according to this alteration, the voltage rises and falls at the output node out and the inverted output node outb can be hastened, and this permits speedup of the circuit.

While in “Alteration” above, an alteration of the first embodiment was described, a similar alteration is also applicable to the second embodiment or the third embodiment, and similar effects are obtained. Specifically, for example, the example of providing the capacitor C1 and the capacitor C2 in addition to the configuration of the first embodiment was described in the above alteration. In the second embodiment and the third embodiment, also, the capacitor C1 and the capacitor C2 may be provided at the same positions as those in the first embodiment, and equal effects can be obtained. Also, in the second embodiment and the third embodiment, the pullup circuit 30 of FIG. 7 may be provided in place of the pullup circuit 30 of FIG. 2, and equal effects can be obtained.

The level shifter circuit according to the present disclosure responds to the trend toward lower operating voltages and/or the speedup of circuit operation, and therefore is very useful.

1. A level shifter circuit, comprising:
an input node receiving an input signal that makes a transition between a first power supply and a second power supply lower in potential than the first power supply;
a first n-type transistor provided between the input node and a first node and having a gate connected to the first power supply;
a first p-type transistor provided between the first node and an output node and having a gate connected to the first power supply;
a second p-type transistor provided between the output node and the first power supply and having a gate connected to the first node;
an inverted input node receiving an inverted input signal inverted from the input signal;
a second n-type transistor provided between the inverted input node and a second node and having a gate connected to the first power supply;
a third p-type transistor provided between the second node and a third node and having a gate connected to the first power supply;
a fourth p-type transistor provided between the third node and the first power supply and having a gate connected to the second node; and
a pullup circuit provided between the first node and the second node, wherein
the pullup circuit includes
a first pullup circuit for pulling up the second node to a third power supply higher in potential than the first power supply when the first node makes a transition from High level to Low level, and
a second pullup circuit for pulling up the first node to the third power supply when the second node makes a transition from High level to Low level.

2. The level shifter circuit of claim 1, wherein
the first pullup circuit includes
a fifth p-type transistor provided between the first node and a fourth node and having a gate connected to the first power supply,
a sixth p-type transistor provided between the fourth node and the first power supply and having a gate connected to the first node,
a seventh p-type transistor provided between the third power supply and a fifth node and having a gate connected to the fourth node, and
an eighth p-type transistor provided between the fifth node and the second node and having a gate connected to the first power supply, and
the second pullup circuit includes
a ninth p-type transistor provided between the second node and a sixth node and having a gate connected to the first power supply,
a tenth p-type transistor provided between the sixth node and the first power supply and having a gate connected to the second node,
an eleventh p-type transistor provided between the third power supply and a seventh node and having a gate connected to the sixth node, and
a twelfth p-type transistor provided between the seventh node and the first node and having a gate connected to the first power supply.

3. The level shifter circuit of claim 2, further comprising:
a thirteenth p-type transistor provided between the third power supply and the output node and having a gate connected to the sixth node; and
a fourteenth p-type transistor provided between the third power supply and the third node and having a gate connected to the fourth node.

4. The level shifter circuit of claim 2, wherein
the first pullup circuit includes a first capacitive element provided between the first node and the fourth node, and
the second pullup circuit includes a second capacitive element provided between the second node and the sixth node.

5. The level shifter circuit of claim 1, further comprising:
a thirteenth p-type transistor provided between the third power supply and the output node and having a gate connected to the third node; and
a fourteenth p-type transistor provided between the third power supply and the third node and having a gate connected to the output node.

6. The level shifter circuit of claim 1, further comprising:
a first capacitive element provided between the first node and the output node; and
a second capacitive element provided between the second node and the third node.
